(19) United States
(12) Patent Application Publication
(10) Pub. No.: US 2010/0255216 A1
(43) Pub. Date: Oct. 7, 2010

(54) PROCESS AND APPARATUS FOR ATMOSPHERIC PRESSURE PLASMA ENHANCED CHEMICAL VAPOR DEPOSITION COATING OF A SUBSTRATE

(76) Inventors: Robert P. Haley, JR., Midland, MI (US); Christina A. Rhoton, Bentley, MI (US); Alphonsus J.P. De Rijcke, Kloosterzande (NL); Mark G.C. Vreys, Oostakker (BE)

Correspondence Address: The Dow Chemical Company, P.O. BOX 1967, Midland, MI, 48641, US

(21) Appl. No.: 12/742,579

(22) PCT Filed: Oct. 27, 2008
(86) PCT No.: PCT/US08/81249

§ 371 Date: May 12, 2010

Related U.S. Application Data
(63) Continuation-in-part of application No. 11/998,280, filed on Nov. 29, 2007.

(51) Int. Cl. C23C 16/50; C23C 16/00

(52) U.S. Cl. 427/569; 118/723 E

(57) ABSTRACT

The invention relates to a process and apparatus for atmospheric pressure plasma enhanced chemical vapor deposition coating using a first electrode (33) and a second electrode (34). The second electrode is positioned apart from the first electrode thereby defining a volume space (42) between the first and second electrodes which volume space is covered by a duct sealed to the electrodes. Gas is flowed from the volume space between the first and second electrodes at the same or at a greater flow rate than the sum of gaseous coating precursor mixtures flowed to the first and second electrodes. In addition, the invention relates to an improved electrode assembly for use in an atmospheric pressure plasma enhanced chemical vapor deposition coating system. The electrode assembly includes a means for distributing a gaseous coating precursor mixture to emerge from an electrode assembly. The improvement relates to a gas distributing subassembly of the electrode assembly.

### BACKGROUND OF THE INVENTION

The instant invention is in the field of plasma enhanced chemical vapor deposition

(PECVD) methods and apparatus for coating substrates and more specifically to PECVD methods and apparatus for applying two or more successive PECVD coatings.

A Plasma is an ionized form of gas that can be obtained by ionizing a gas or liquid medium using an AC or DC power source. A plasma, commonly referred to as the fourth state of matter, is an ensemble of randomly moving charged particles with sufficient density to remain, on average, electrically neutral. Plasmas are used in very diverse processing applications, ranging from the manufacture of integrated circuits for the microelectronics industry, to the treatment of fabric and the destruction of toxic wastes.

Plasmas are widely used for the treatment of organic and inorganic surfaces to promote adhesion between various materials. For example, polymers that have chemically inert surfaces with low surface energies do not allow good bonding with coatings and adhesives. Thus, these surfaces need to be treated in some way, such as by chemical treatment, corona treatment, flame treatment, and vacuum plasma treatment, to make them receptive to bonding with other substrates, coatings, adhesives and printing inks. Corona discharge, physical sputtering, plasma etching, reactive ion etching, sputter deposition, PECVD, ashing, ion plating, reactive sputter deposition, and a range of ion beam-based techniques, all rely on the formation and properties of plasmas.

The use of PECVD techniques to coat an object with, for example, a silicon oxide layer and/or a polyorganosiloxane layer by introducing a “precursor” into a plasma adjacent to the object to be coated is well known as described, for example, in WO 2004/044039 A2. PECVD can be conducted in a reduced pressure chamber or in the open at or near atmospheric pressure as described, for example, in U.S. Pat. Nos. 6,118,218 and 6,441,553. PECVD conducted at or near atmospheric pressure has the advantage of lower equipment costs and more convenient manipulation of the substrates to be coated.

Two different types of electrode systems are generally used for atmospheric pressure PECVD coating. The first such system is termed a “top-down” electrode system wherein the object to be coated is positioned between a working electrode and a grounded electrode. The plasma is generated between the working electrode and the object to be coated and the precursor is introduced into the plasma by way of a carrier gas usually comprising oxygen and an inert gas such as argon. The second such electrode system is termed a “side-by-side” electrode system and comprises a grounded electrode(s) and a working electrode(s) embedded in a dielectric material such as a ceramic. The plasma is generated adjacent the surface of the dielectric material. The surface of the object to be coated is exposed to the plasma while the precursor is introduced into the plasma by way of a carrier gas usually comprising oxygen and an inert gas such as argon. The mixture of precursor material(s) with the carrier gas is called a “gaseous precursor mixture”.

Atmospheric pressure PECVD coating systems can produce irritating or toxic emissions as a byproduct resulting from the passage of the gaseous precursor mixture through the plasma. Such emissions are traditionally vented in a safe manner from a hood placed over the atmospheric pressure PECVD coating system. However, the instant inventors have found that the use of such hoods can interfere with desired flow patterns as well as air contamination of the gaseous precursor mixture through the plasma especially when two or more electrodes are used to sequentially generate two or more PECVD coatings on a substrate.

### SUMMARY OF THE INVENTION

The instant invention provides a process and apparatus for venting gases from an atmospheric pressure PECVD coating system employing two or more electrodes while maintaining excellent flow patterns of the gaseous precursor mixtures through the plasmas and elimination of air contamination of the gaseous precursor mixtures thereby improving the uniformity of and chemistry of the coatings on the substrate. More specifically, the instant invention is a process for operating an atmospheric pressure plasma enhanced chemical vapor deposition coating system, the process comprising steps of: introducing a first gaseous coating precursor mixture and second gaseous coating precursor mixture into a first plasma and second plasma electrically generated adjacent to a plasma surface of a first and plasma surface of a second electrode, the second electrode being positioned apart from the first electrode so that the plasma surface of the first electrode is substantially parallel with the plasma surface of the second electrode thereby defining a volume space between the first and second electrodes; and flowing gas from the volume space between the first and second electrodes at the same or at a greater flow rate than a summed flow rate that is the sum of respective first and second flow rates that the first and second gaseous coating precursor mixtures are introduced into the first and second plasmas.

In another embodiment, the instant invention is an apparatus for an atmospheric pressure plasma enhanced chemical vapor deposition coating system, comprising: a first electrode and a second electrode, means for introducing a first gaseous coating precursor mixture into a plasma generated adjacent to a plasma surface of the first electrode, means for introducing a second gaseous coating precursor mixture into a plasma generated adjacent to a plasma surface of the second electrode, the second electrode being positioned apart from the first electrode so that the plasma surface of the first electrode is substantially parallel with the plasma surface of the second electrode thereby defining a volume space between the first and second electrodes, a duct positioned over the volume space between the first and second electrodes, the duct sealed to the first and second electrodes so that when the apparatus is placed on a sheet of material, the volume space between the first and second electrodes is substantially bounded by the electrodes, the duct and the sheet of material.

In yet another embodiment, the instant invention is an improved electrode assembly for use in an atmospheric pressure plasma enhanced chemical vapor deposition coating system comprising a means for distributing a gaseous coating precursor mixture to emerge from an electrode assembly, wherein the improvement comprises a subassembly of the electrode assembly, the subassembly comprising at least one planar surface having an ovoidal groove therein and a ledge therein adjacent the ovoidal groove, the ovoidal groove having a straight section, the ledge being positioned between the straight section of the ovoidal groove and an edge of the subassembly, the surface of the ledge being below the planar surface and extending from the straight section of the ovoidal groove to the edge of the subassembly, the subassembly further comprising a first and a second passageway therethrough for the passage of a gaseous coating precursor mixture therethrough, the first passageway terminating at one end thereof at a position substantially at the center of the straight section of the ovoidal groove, the second passageway terminating at one end thereof at a position substantially equidistant in both directions along the ovoidal groove from the center of the straight section of the ovoidal groove.

### BRIEF DESCRIPTION OF THE DRAWINGS

FIG. 1 is a cross-sectional side view of a prior art two electrode atmospheric pressure PECVD coating system employing a hood to evacuate fumes from the system;

FIG. 2 is a cross-sectional side view of a two electrode atmospheric pressure PECVD coating system of the instant invention employing a duct to evacuate fumes from the system and wherein the gaseous coating precursor mixtures emerge from apertures in the electrode assemblies;

FIG. 3 is an end view of the system shown in FIG. 2;

FIG. 4 is a cross-sectional side view of a two electrode atmospheric pressure PECVD coating system of the instant invention employing a duct to evacuate fumes from the system and wherein the gaseous coating precursor mixtures are flowed under the electrode assemblies from plenums positioned above and to one side of the electrode assemblies;

FIG. 5 is an end view of the system shown in FIG. 3;

FIG. 6 is a cross-sectional end view of a preferred side-by-side electrode assembly for use in the instant invention comprising a central ceramic section containing alternate ground and high voltage rods and metal side sections for coolant passageways, one of which side section comprises a preferred distributor for flowing the gaseous coating precursor mixture from the electrode assembly;

FIG. 7 is a top view of the preferred distributor for flowing the gaseous coating precursor mixture from the electrode assembly of FIG. 6;

FIG. 8 is a cross-sectional side view of the preferred distributor of FIG. 7;

FIG. 9 is a cross-sectional end view of a preferred top-down electrode assembly for use in the instant invention comprising a central metallic high voltage section and ceramic side sections for coolant passageways, one of which side section comprises a preferred distributor for flowing the gaseous coating precursor mixture from the electrode assembly and a ground electrode positioned under the substrate to be coated; and

FIG. 10 is a bottom view of a top-down electrode assembly for use in the instant invention comprising a central metallic high voltage section and ceramic side sections for coolant passageways, one of which side section comprises apertures for flowing the gaseous coating precursor mixture from the electrode assembly.

### DETAILED DESCRIPTION

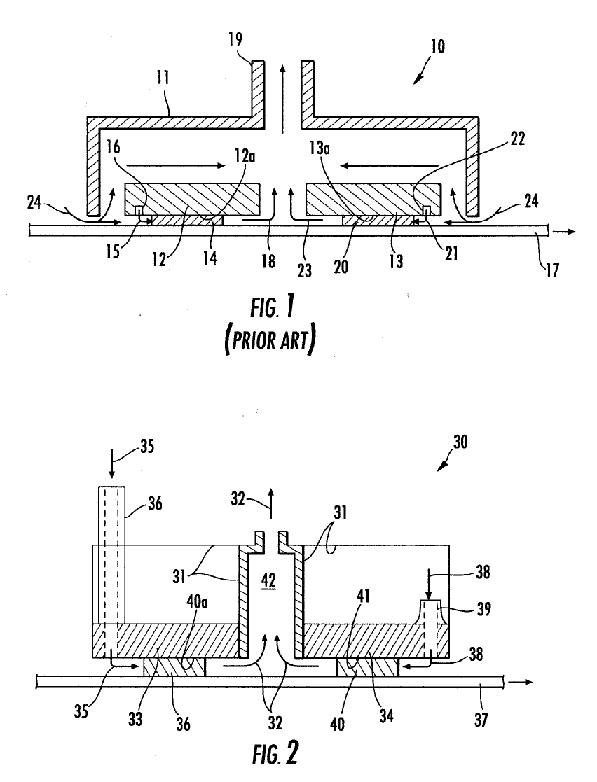

Referring now to FIG. 1, therein is shown a cross-sectional side view of a prior art two electrode atmospheric pressure PECVD coating system 10 employing a hood 11 to evacuate fumes from the system. The system 10 includes a first electrode assembly 12 and a second electrode assembly 13. A first plasma 14 is generated adjacent the plasma surface 12a of the first electrode 12. A first gaseous coating precursor mixture 15 is flowed from a slot 16 in the electrode assembly 12. The first gaseous coating precursor mixture 15 passes through the plasma 14 to coat a moving substrate 17 with a first PECVD coating. Fumes 18 from the plasma 14 are drawn out the outlet 19 of the hood 11. A second plasma 20 is generated adjacent the plasma surface 13a of the second electrode 13. A second gaseous coating precursor mixture 21 is flowed from a slot 22 in the electrode assembly 13. The second gaseous coating precursor mixture 21 passes through the plasma 20 to coat a moving substrate 17 with a second PECVD coating. Fumes 23 from the plasma 20 are drawn out the outlet 19 of the hood 11. The flow rate out of the outlet 19 of the hood 11 is significantly greater than the sum of the flow rates of the first and second gaseous coating precursor mixtures 15 and 21 to ensure that excess air 24 flows under the edge of the hood 11 so that no fumes escape the edges of the hood. Some of the excess air 24 undesirably flows with the gaseous coating precursor mixtures 15 and 21 into the plasmas 14 and 20 respectively.

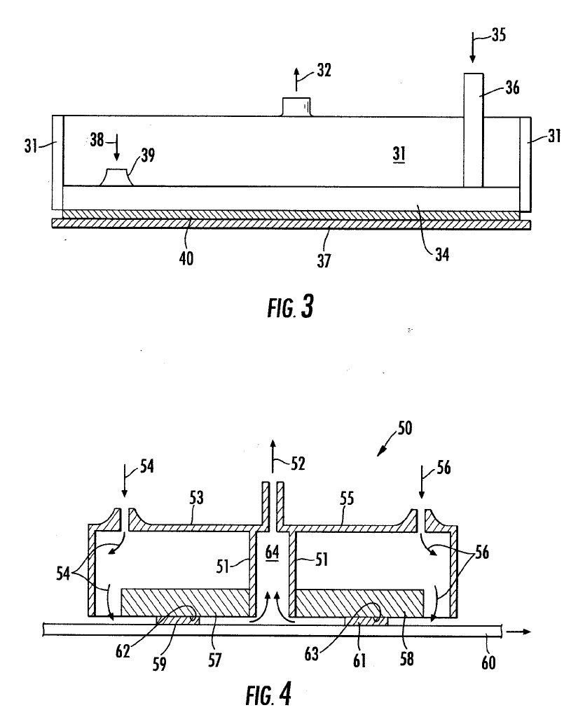

Referring now to FIG. 2, therein is shown a cross-sectional side view of a two electrode atmospheric pressure PECVD coating system 30 of the instant invention employing a duct 31 to evacuate fume gas 32 from the system 30. The system 30 comprises a first electrode assembly 33 and a second electrode assembly 34. The term “electrode assembly” means an assembly comprising an electrode and optionally additional elements for, for example, cooling the electrode assembly and for introducing gaseous coating precursor mixtures into a plasma electrically generated adjacent a surface of the electrode. A first gaseous coating precursor mixture 35 is flowed through conduit 36, through the electrode assembly 33, through a plasma 36 to produce a first PECVD coating on a moving substrate sheet 37 and fumes 32. A second gaseous coating precursor mixture 38 is flowed through conduit 39, through the electrode assembly 34, through a plasma 40 to produce a second PECVD coating on the moving substrate sheet 37 and fumes 32. The first electrode assembly 34 is positioned apart from the first electrode assembly 33 so that the plasma surface 40a of the first electrode assembly 33 is substantially parallel with and substantially in the same plane as the plasma surface 41 of the first electrode assembly 34 thereby defining a volume space 42 between the first and second electrodes. The duct 31 is positioned over the volume space 42 between the first and second electrode assemblies 33 and 34. The duct 31 is sealed to the first and second electrode assemblies 33 and 34 so that when the system 30 is placed on a sheet of material (such as the substrate sheet 37), the volume space 42 between the first and second electrode assemblies 33 and 34 is substantially bounded by the electrode assemblies 33 and 34, the duct 31 and the sheet of material. The flow rate of fume gas 32 from the volume space 42 between the first and second electrode assemblies 33 and 34 is at the same or at a greater flow rate than the sum of the flow rates of the first and second gaseous coating precursor mixtures 35 and 38. Preferably, the flow rate of fume gas 32 from the volume space 42 between the first and second electrode assemblies 33 and 34 is from equal to 1.1 times greater than the sum of the flow rates of the first and second gaseous coating precursor mixtures 35 and 38. More preferably, the flow rate of fume gas 32 from the volume space 42 between the first and second electrode assemblies 33 and 34 is from equal to 1.01 times greater than the sum of the flow rates of the first and second gaseous coating precursor mixtures 35 and 38. Referring now to FIG. 3, therein is shown an end view of the system 30 of FIG. 2.

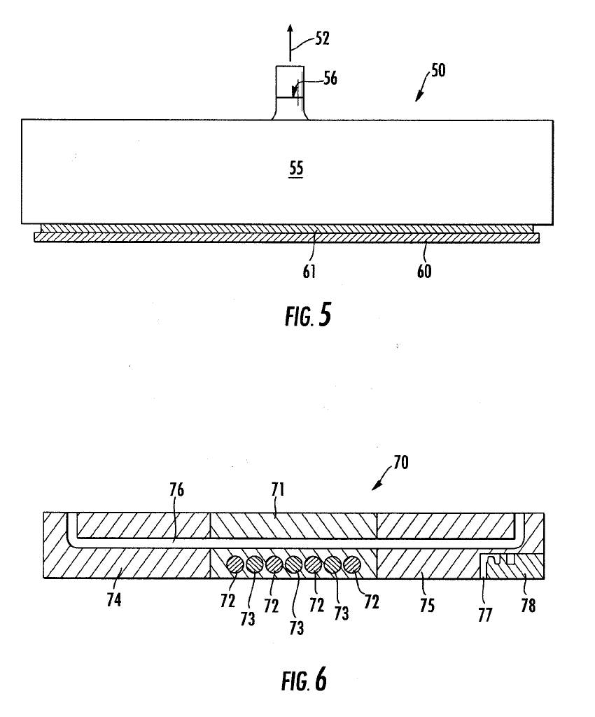

Referring now to FIG. 4, therein is shown a cross-sectional side view of a two electrode atmospheric pressure PECVD coating system 50 of the instant invention employing a duct 51 to evacuate fume gas 52 from the system 50. The system 50 comprises a first plenum 53 into which a first gaseous coating precursor mixture 54 is flowed. The system 50 comprises a second plenum 55 into which a second gaseous coating precursor mixture 56 is flowed. The system 50 comprises a first electrode assembly 57 and a second electrode assembly 58. The first gaseous coating precursor mixture 54 is flowed through a plasma 59 to produce a first PECVD coating on a moving substrate sheet 60 and fumes 52. The second gaseous coating precursor mixture 56 is flowed through a plasma 61 to produce a second PECVD coating on the moving substrate sheet 60 and fumes 52. The second electrode assembly 58 is positioned apart from the first electrode assembly 57 so that the plasma surface 62 of the first electrode assembly 57 is substantially parallel with and substantially in the same plane as the plasma surface 63 of the second electrode assembly 58 thereby defining a volume space 64 between the first and second electrode assemblies 57 and 58. The duct 31 is positioned over the volume space 42 between the first and second electrode assemblies 33 and 34. The duct 51 is sealed to the first and second electrode assemblies 57 and 58 so that when the system 50 is placed on a sheet of material (such as the substrate sheet 60), the volume space 64 between the first and second electrode assemblies 57 and 58 is substantially bounded by the electrode assemblies 57 and 58, the duct 51 and the sheet of material. The flow rate of fume gas 52 from the volume space 64 between the first and second electrode assemblies 57 and 58 is at the same or at a greater flow rate than the sum of the flow rates of the first and second gaseous coating precursor mixtures 54 and 56. Preferably, the flow rate of fume gas 52 from the volume space 64 between the first and second electrode assemblies 57 and 58 is from equal to 1.1 times greater than the sum of the flow rates of the first and second gaseous coating precursor mixtures 54 and 56. More preferably, the flow rate of fume gas 52 from the volume space 64 between the first and second electrode assemblies 57 and 58 is from equal to 1.01 times greater than the sum of the flow rates of the first and second gaseous coating precursor mixtures 54 and 56. Referring now to FIG. 5, therein is shown an end view of the system 50 of FIG. 4.

Referring now to FIG. 6, therein is shown a cross-sectional end view of a preferred side-by-side electrode assembly 70 for use in the instant invention comprising a central ceramic section 71 containing alternate ground 72 and high voltage 73 metallic rods, a first metallic side section 74 and a second metallic side section 75. In use, a coolant fluid is passed through passageways in the electrode assembly 70 one of which passageway is shown as passageway 76. The second metallic side section 75 comprises a preferred distributor 78 for flowing a gaseous coating precursor mixture from the electrode assembly by way of slot 77.

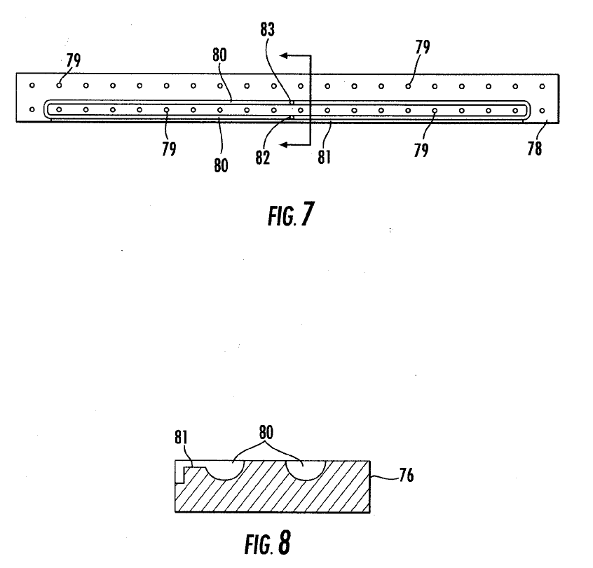

Referring now to FIG. 7, therein is shown a top view of the distributor 78 of FIG. 6 showing holes 79 through which screws are passed to attach the distributor 78 to the second metallic side section 75. An ovoidal track 80 is machined into the distributor 78. A gaseous coating precursor mixture is flowed via passageways 82 and 83 into the center of each straight leg of the ovoidal track 80. The gaseous coating precursor mixture flows over the ledge 81 and into the slot 77 shown in FIG. 6. It is believed that the introduction of the gaseous coating precursor mixture into the ovoidal track 80 by way of the passageways 82 and 83 results in an essentially constant flow rate of the gaseous coating precursor mixture from all locations along the length of the slot 77. Referring now to FIG. 8, therein is shown an enlarged cross-sectional end view of the distributor 78.

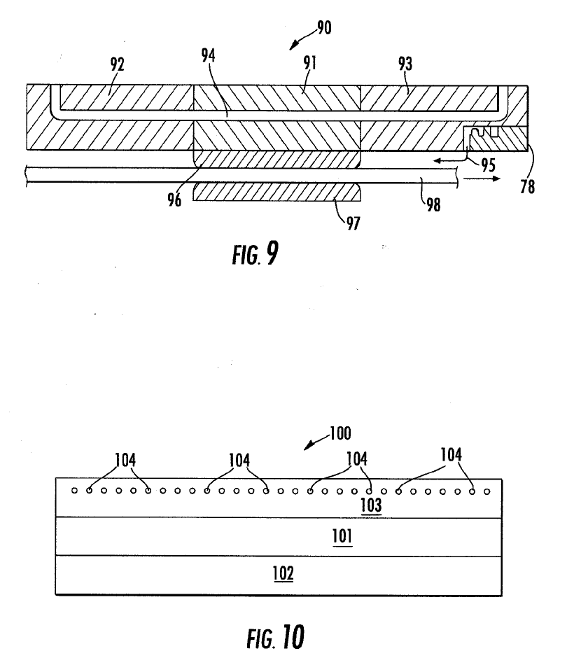

Referring now to FIG. 9, therein is shown a cross-sectional end view of a preferred side-by-side electrode assembly 90 for use in the instant invention comprising a central high voltage metallic section 91, a first ceramic side section 92 and a second ceramic side section 93. In use, a coolant fluid is passed through passageways in the electrode assembly 90 one of which passageway is shown as passageway 94. The second ceramic side section 93 comprises the preferred distributor 78 of FIGS. 6, 7 and 8 for flowing a gaseous coating precursor mixture 95 from the electrode assembly 90. In practice, a plasma 96 is generated adjacent the electrode 91, above a moving substrate sheet 98 which is moved above a ground electrode 97. Passage of the gaseous coating precursor mixture 95 through the plasma 96 generates a PECVD coating on a moving substrate sheet 98.

Referring now to FIG. 10, therein is shown a bottom view of a top-down electrode assembly 100 for use in the instant invention comprising a central metallic high voltage section 101 a first ceramic side section 102, and a second ceramic side section 103. The second ceramic side section 103 has a plurality of apertures 104 thereinto for flowing a gaseous coating precursor mixture from the electrode assembly 100.

Any combination of suitable gaseous coating precursor mixtures and electrode operating conditions can be used in the instant invention. For example, an adhesion coating (a coating that improves the adhesion of a subsequent coating to a substrate as disclosed, for example, in U.S. Pat. No. 5,718,967) can first be deposited on a substrate using a precursor mixture comprising hexamethyldisiloxane and oxygen. Then the adhesion coating can be coated with an abrasion resistant coating using a precursor mixture comprising, for example, tetramethyldisiloxane. The electrode operating conditions outlined in WO 03066932 can, for example, be used in the process and apparatus of the instant invention.

### CONCLUSION

While the instant invention has been described above according to its preferred embodiments, it can be modified within the spirit and scope of this disclosure. This application is therefore intended to cover any variations, uses, or adaptations of the instant invention using the general principles disclosed herein. Further, the instant application is intended to cover such departures from the present disclosure as come within the known or customary practice in the art to which this invention pertains and which fall within the limits of the following claims.

What is claimed is:

1. A process for operating an atmospheric pressure plasma enhanced chemical vapor deposition coating system, the process comprising steps of: introducing a first gaseous coating precursor mixture and second gaseous coating precursor mixture into a first plasma and second plasma electrically generated adjacent to a plasma surface of a first electrode and plasma surface of a second electrode, the second electrode being positioned apart from the first electrode so that the plasma surface of the first electrode is substantially parallel with the plasma surface of the second electrode thereby defining a volume space between the first and second electrodes; and flowing gas from the volume space between the first and second electrodes at the same or at a greater flow rate than a summed flow rate that is the sum of respective first and second flow rates that the first and second gaseous coating precursor mixtures are introduced into the first and second plasmas.

2. The process of claim 1, wherein gas is flowed from the volume space between the first and second electrodes at a flow rate equal to or more than 1.1 times the summed flow rate that is the sum of the respective flow rates that the first and second gaseous coating precursor mixtures are introduced into the first and second plasmas.

3. The process of claim 1, wherein gas is flowed from the volume space between the first and second electrodes at a flow rate equal to or more than 1.01 times the summed flow rate that is the sum of the respective flow rates that the first and second gaseous coating precursor mixtures are introduced into the first and second plasmas.

4. Apparatus for an atmospheric pressure plasma enhanced chemical vapor deposition coating system, comprising: a first electrode and a second electrode, a means for introducing a first gaseous coating precursor mixture into a plasma generated adjacent to a plasma surface of the first electrode, a means for introducing a second gaseous coating precursor mixture into a plasma generated adjacent to a plasma surface of the second electrode, the second electrode being positioned apart from the first electrode so that the plasma surface of the first electrode is substantially parallel with the plasma surface of the second electrode thereby defining a volume space between the first and second electrodes, a duct positioned over the volume space between the first and second electrodes, the duct sealed to the first and second electrodes so that when the apparatus is placed on a sheet of material, the volume space between the first and second electrodes is substantially bounded by the electrodes, the duct and the sheet of material.

5. The apparatus of claim 4, wherein the means for introducing the first gaseous coating precursor mixture into a plasma generated adjacent to a plasma surface of the first electrode is at least one aperture in the first electrode from which the first gaseous coating precursor mixture can emerge and wherein the means for introducing the second gaseous coating precursor mixture into a plasma generated adjacent to a plasma surface of the second electrode is at least one aperture in the second electrode from which the second gaseous coating precursor mixture can emerge.

6. The apparatus of claim 5, wherein the at least one aperture in the first electrode is a slot and wherein the at least one aperture in the second electrode is a slot.

7. The apparatus of claim 4, wherein the means for introducing the first gaseous coating precursor mixture into a plasma generated adjacent to a plasma surface of the first electrode is a plurality of apertures in the first electrode from which the first gaseous coating precursor mixture can emerge and wherein the means for introducing the second gaseous coating precursor mixture into a plasma generated adjacent to a plasma surface of the second electrode is a plurality of apertures in the second electrode from which the second gaseous coating precursor mixture can emerge.

8. The apparatus of claim 4, wherein the means for introducing the first gaseous coating precursor mixture into a plasma generated adjacent to a plasma surface of the first electrode is a chamber adjacent the first electrode from which the first gaseous coating precursor mixture can flow into the plasma generated adjacent to the plasma surface of the first electrode and wherein the means for introducing the second gaseous coating precursor mixture into a plasma generated adjacent to a plasma surface of the second electrode is a chamber adjacent the second electrode from which the second gaseous coating precursor mixture can flow into the plasma generated adjacent to the plasma surface of the second electrode.

9. An improved electrode assembly for use in an atmospheric pressure plasma enhanced chemical vapor deposition coating system comprising a means for distributing a gaseous coating precursor mixture to emerge from an electrode assembly, wherein the improvement comprises a subassembly of the electrode assembly, the subassembly comprising an edge, at least one planar surface having an ovoidal groove therein and a ledge therein adjacent the ovoidal groove, the ovoidal groove having a straight section having a center, the ledge having a surface and being positioned between the straight section of the ovoidal groove and the edge of the subassembly, the surface of the ledge being below the planar surface and extending from the straight section of the ovoidal groove to the edge of the subassembly, the subassembly further comprising a first and a second passageway therethrough for the passage of a gaseous coating precursor mixture therethrough, the first passageway terminating at one end thereof at a position substantially at the center of the straight section of the ovoidal groove, the second passageway terminating at one end thereof at a position substantially equidistant in both directions along the ovoidal groove from the center of the straight section of the ovoidal groove.
